(19) United States
(12) Patent Application Publication
(10) Pub. No.: US 2022/0137279 A1
(43) Pub. Date: May 5, 2022

(54) SIMPLIFIED GEOMETRY FOR FABRICATION OF POLARIZATION-BASED ELEMENTS

(71) Applicant: Teledyne Scientific & Imaging, LLC, Thousand Oaks, CA (US)

(72) Inventors: Milind Mahajan, Thousand Oaks, CA (US); Bryce Murray, Thousand Oaks, CA (US); Dong-Feng Gu, Thousand Oaks, CA (US)

(21) Appl. No.: 17/089,419

(22) Filed: Nov. 4, 2020

(51) Int. Cl. G02B 5/32; G03H 1/04; G02B 5/30; G02F 1/13363

(52) U.S. Cl. CPC G02B 5/32; G03H 1/04; G02F 1/13363; G02B 5/3083; G02B 5/3016

(57) ABSTRACT

Disclosed are various methods for creating optical elements through holographic fabrication. One method includes positioning a reflector in an optical path, disposing a first substrate proximal to the reflector along the optical path, disposing a first photosensitive film on the side of the first substrate facing the reflector, transmitting a light beam at a first polarization from a light source along the optical path, reflecting the light beam off the reflector, wherein the reflected light beam has a second polarization, receiving the reflected light beam through the first film and the first substrate, and applying a liquid crystal layer to the first photosensitive film to reproduce the alignment pattern of the first film on the liquid crystal layer.

### BACKGROUND

The present disclosure relates to the manufacturing of optical elements that can direct, focus, or diffuse light. Some of the applications for these optical elements comprise non-mechanical beam steering, field of view expansion, field of view switching, and laser collimation.

### SUMMARY

In various aspects, the present disclosure provides use of a single reflective element to simplify holographic fabrication of polarization based optical elements.

In one general aspect, the present disclosure provides a method for creating optical elements through holographic fabrication. In one aspect, the method comprises positioning a reflector in an optical path, disposing a first photosensitive film on a side of a first substrate, and disposing the first substrate proximal to the reflector along the optical path, wherein the side of the first substrate with the first photosensitive film faces the reflector and another side faces away from the reflector. The method further comprises transmitting a light beam at a first polarization from a light source along the optical path, wherein the light beam enters the first substrate on the side facing away from the reflector and exits the first substrate on the side facing the reflector with the first photosensitive film and continues toward the reflector. The method further comprises reflecting the light beam off the reflector, wherein the reflected light beam has a second polarization, and receiving the reflected light beam through the first photosensitive film and the first substrate. The transmitted light beam and reflected light beam interfere with each other to produce a polarization pattern that is transferred to an alignment pattern of the first photosensitive film. The method further comprises applying a liquid crystal layer to the first photosensitive film to reproduce the alignment pattern of the first photosensitive film on the liquid crystal layer.

In another aspect, the present disclosure provides a birefringent optical element produced by a method comprising positioning a reflector in an optical path, disposing a first photosensitive film on a side of a first substrate, and disposing the first substrate proximal to the reflector along the optical path, wherein the side of the first substrate with the first photosensitive film faces the reflector and another side faces away from the reflector. The method further comprises transmitting a light beam at a first polarization from a light source along the optical path, wherein the light beam enters the first substrate on the side facing away from the reflector and exits the first substrate on the side facing the reflector with the first photosensitive film and continues toward the reflector. The method further comprises reflecting the light beam off the reflector, wherein the reflected light beam has a second polarization, and receiving the reflected light beam through the first film and the first substrate, wherein the transmitted light beam and reflected light beam interfere with each other to produce a polarization pattern that is transferred to an alignment pattern of the first photosensitive film. The method further comprises applying a liquid crystal layer to the first film to reproduce the alignment pattern of the first film on the liquid crystal layer, applying the liquid crystal layer by coating the liquid crystal layer onto the first film to a predetermined thickness, and polymerizing the liquid crystal layer to lock the structure of the liquid crystal layer. Various methods can be used for coating or solvent casting, like dip coating, spray coating, meniscus coating, metering rod etc.

In another aspect, the present disclosure provides a birefringent optical element produced by a method comprising positioning a reflector in an optical path, disposing a first photosensitive film on a side of a first substrate, and disposing the first substrate proximal to the reflector along the optical path, wherein the side of the first substrate with the first photosensitive film faces the reflector and another side faces away from the reflector. The method further comprises transmitting a light beam at a first polarization from a light source along the optical path, wherein the light beam enters the first substrate on the side facing away from the reflector and exits the first substrate on the side facing the reflector with the first film and continues toward the reflector. The method further comprises reflecting the light beam off the reflector, wherein the reflected light beam has a second polarization, and receiving the reflected light beam through the first photosensitive film and the first substrate, wherein the transmitted light beam and reflected light beam interfere with each other to produce a polarization pattern that is transferred to an alignment pattern of the first film. The method further comprises providing a second substrate comprising a second film layer disposed on a surface of the second substrate, and positioning a thickness spacer on the first substrate against the first film, wherein the thickness of the spacer is the thickness of a liquid crystal layer. The method further comprises applying the liquid crystal layer by filling the volume inside of the spacer with liquid crystal, and positioning and attaching the second substrate against the spacer, wherein the liquid crystal is directly between the first and second film and held in place by the surrounding spacer.

In another aspect, the present disclosure provides a method for creating optical elements through holographic fabrication. In one aspect, the method comprises positioning a curved reflector in an optical path, disposing a first photosensitive film on a side of a first substrate, disposing the first substrate proximal to the reflector along the optical path, wherein the side of the first substrate with the first photosensitive film faces the reflector and another side faces away from the reflector. The method further comprises transmitting a light beam at a first polarization from a light source along the optical path, wherein the light beam enters the first substrate on the side facing away from the reflector and exits the first substrate on the side facing the reflector with the first photosensitive film and continues toward the reflector. The method further comprises reflecting the light beam off the reflector, wherein the reflected light beam has a second polarization, and receiving the reflected light beam through the first photosensitive film and the first substrate, wherein the transmitted light beam and reflected light beam interfere with each other to produce a polarization pattern that is transferred to an alignment pattern of the first film. The method further comprises applying a liquid crystal layer to the first film to reproduce the alignment pattern of the first film on the liquid crystal layer.

In another aspect, the present disclosure provides a birefringent lens produced by a method comprising positioning a curved reflector in an optical path, disposing a first photosensitive film on a side of a first substrate, and disposing the first substrate proximal to the reflector along the optical path, wherein the side of the first substrate with the first photosensitive film faces the reflector and another side faces away from the reflector. The method further comprises transmitting a light beam at a first polarization from a light source along the optical path, wherein the light beam enters the first substrate on the side facing away from the reflector and exits the first substrate on the side facing the reflector with the first photosensitive film and continues toward the reflector. The method further comprises reflecting the light beam off the reflector, wherein the reflected light beam has a second polarization, and receiving the reflected light beam through the first film and the first substrate, wherein the transmitted light beam and reflected light beam interfere with each other to produce a polarization pattern that is transferred to an alignment pattern of the first photosensitive film. The method further comprises applying a liquid crystal layer to the first film to reproduce the alignment pattern of the first photosensitive film on the liquid crystal layer, applying the liquid crystal layer by coating the liquid crystal layer onto the first film to a predetermined thickness, and polymerizing the liquid crystal layer to lock the structure of the liquid crystal layer.

In another aspect, the present disclosure provides a birefringent lens produced by a method comprising positioning a curved reflector in an optical path, disposing a first photosensitive film on a side of a first substrate, and disposing the first substrate proximal to the reflector along the optical path, wherein the side of the first substrate with the first photosensitive film faces the reflector and another side faces away from the reflector. The method further comprises transmitting a light beam at a first polarization from a light source along the optical path, wherein the light beam enters the first substrate on the side facing away from the reflector and exits the first substrate on the side facing the reflector with the first photosensitive film and continues toward the reflector. The method further comprises reflecting the light beam off the reflector, wherein the reflected light beam has a second polarization, and receiving the reflected light beam through the first film and the first substrate, wherein the transmitted light beam and reflected light beam interfere with each other to produce a polarization pattern that is transferred to an alignment pattern of the first photosensitive film. The method further comprises providing a second substrate comprising a second film layer disposed on a surface of the second substrate, and positioning a thickness spacer around the outside of the first substrate against the first film, wherein the thickness of the spacer is the thickness of the liquid crystal layer. The method further comprises positioning and attaching the second substrate against the spacer, and applying the liquid crystal layer by filling the volume inside of the spacer with liquid crystal, wherein the liquid crystal is directly between the first and second film and held in place by the surrounding spacer.

### BRIEF DESCRIPTION OF THE FIGURES

The novel features of the various aspects are set forth with particularity in the appended claims. The described aspects, however, both as to organization and methods of operation, may be best understood by reference to the following description, taken in conjunction with the accompanying drawings in which:

FIG. 1 is a traditional holographic setup to create optical elements through holographic fabrication.

FIG. 2 is a Wollaston prism based setup to create optical elements through holographic fabrication.

FIG. 3 is a fabrication setup for creating optical elements through holographic fabrication that direct light in accordance with at least one aspect of the resent disclosure.

FIG. 4 is a fabrication setup for creating optical elements through holographic fabrication that focus or diverge light in accordance with at least one aspect of the resent disclosure.

FIG. 5 is a side view of layers of a birefringent optical element with polymerized liquid crystal in accordance with at least one aspect of the resent disclosure.

FIG. 6 is a side view of layers of a birefringent optical element that is not polymerized in accordance with at least one aspect of the resent disclosure.

FIG. 7 is a flow diagram of the method used in FIGS. 3 and 4 in accordance with at least one aspect of the resent disclosure.

### DESCRIPTION

The following description is exemplary in nature and provides some illustrations and examples. Those skilled in the art will recognize that many of the examples have a variety of suitable alternatives. A number of various exemplary holographic fabrication techniques are disclosed herein using the description provided as follows in addition to the accompanying drawings. Each of the aspects disclosed herein can be employed independently or in combination with one or more (e.g., all) of the other aspects disclosed herein.

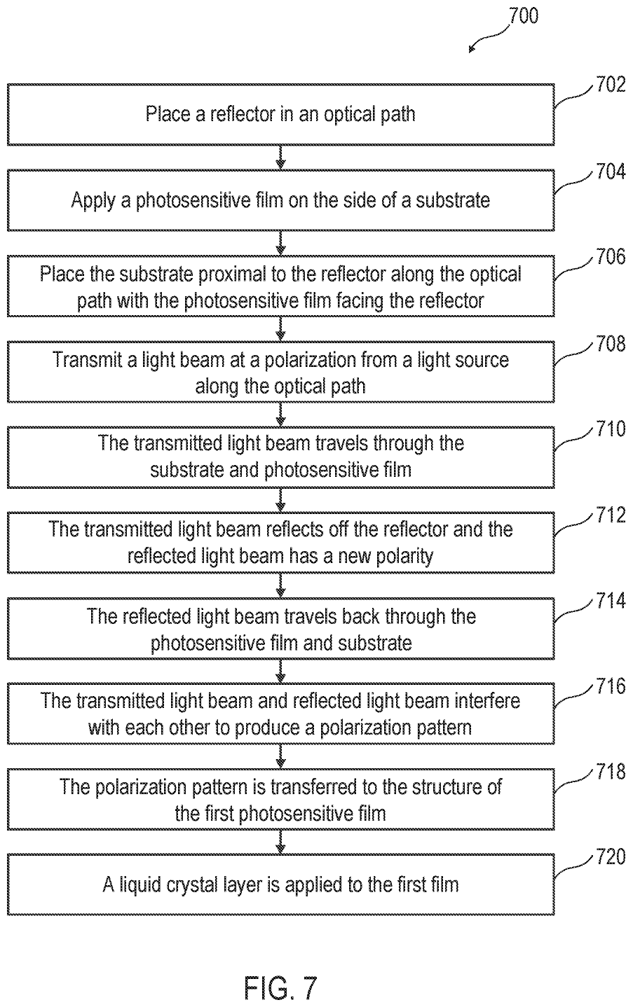

The present disclosure is directed to various aspects of holographic fabrication that can be employed to create birefringent optical elements. In one general aspect, a process is provided that uses two interfering light beams with different polarizations to produce a polarization pattern. This polarization pattern is transferred onto a liquid crystal alignment layer. Then liquid crystal is applied to the alignment layer and the polarization pattern of the alignment layer is reproduced on the liquid crystal. One aspect of a process for creating a birefringent lens described in this disclosure are discussed in FIG. 7.

The specific polarization pattern applied to the liquid crystal changes the type and functionality of the birefringent optical element being created. There are two example types that are discussed in this disclosure. The first is a polarization grating with a linear pitch. If there is light incidence on the grating, then it will deflect one circular polarization in one direction and the orthogonal circular polarization in another direction. The grating will send light in +1 order or −1 order depending on the polarization. Controlling the polarization controls where the grating directs the light. The second example type of birefringent optical element is one that can focus or diverge a light beam. The polarization on one of these optical elements is periodic in a radial fashion. Some of the applications for these optical elements include non-mechanical beam steering, field of view expansion, field of view switching, laser collimation.

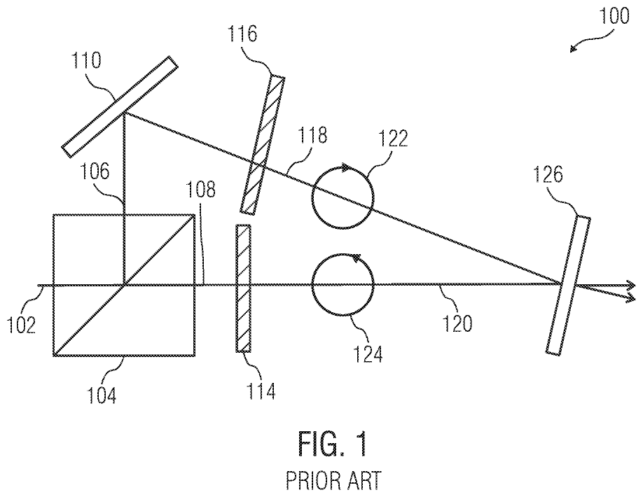

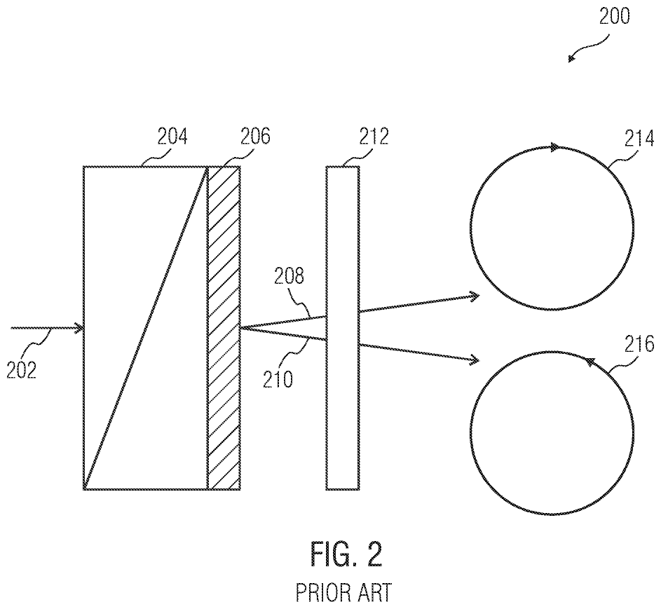

FIGS. 1 and 2 show two main conventional setups for fabricating birefringent optical elements. There are, however, some major challenges in fabricating birefringent optical elements using conventional techniques that relate to the setup being used to create the birefringent optical elements. The first conventional setup shown in FIG. 1 is the traditional holographic setup 100 and the second conventional setup shown in FIG. 2 is a Wollaston prism based holographic setup 200.

Referring first to FIG. 1, the traditional holographic setup 100 includes a light beam 102 that is transmitted along an optical path through a beam splitter 104. The beam splitter 104 splits the light beam 102 into two beams 106, 108. Light beam 108 travels through polarization control 114. The light beam 108 exits the polarization control 114 as light beam 120 with a specific polarization 124. The light beam 120 continues along the optical path to pass through the sample 126. The light beam 106 travels along an optical path and is reflected off of mirror 110. The angle of mirror 110 is controlled to provide a specific optical path for light beam 106 to travel. Light beam 106 then passes through polarization control 116. The light beam 106 exits the polarization control 116 as light beam 118 with a specific polarization 122. The polarization 124 of light beam 120 is orthogonal to the polarization 122 of light beam 118. The light beam 118 continues along its optical path to pass through sample 126. Light beam 118 and light beam 120 interfere with each other and produce a polarization pattern at the sample 126.

The traditional holographic setup 100 becomes challenging when larger diameter birefringent optical elements are manufactured. Large diameter optics are needed for birefringent elements that need to operate over a large distance. A non-limiting example diameter for a large birefringent lens is greater than 1 inch. As the diameter of the optical elements being manufactured increases the diameter of the interfering beams used in fabrication increases. As the interfering beams diameter increases it increases the distance the beams have to travel to maintain an appropriate angle between the beams and the sample. This longer air path the beams travel make the manufacturing more difficult due to needing to control any turbulence in the air path as well as any vibrations in any of the elements involved. The method to overcome these challenges is to make the setup as compact as possible and use as few elements as possible.

Referring to FIG. 2, the Wollaston prism based holographic setup 200 has less elements and is more compact than the traditional holographic setup 100. As shown in FIG. 2, the Wollaston prism based holographic setup has a light beam 202 that is transmitted along an optical path through a Wollaston prism 204 and then through a quarter wave plate 206. The light beam 202 has equal vertical and horizontal polarization with respect to Wollaston prism 204. The Wollaston prism 204 splits the light beam 202 into two beams 208 and 210 that are at an angle in respect to each other and have linear orthogonal polarizations. The quarter wave plate 206 turns the polarizations into right hand circular 216 and left hand circular 214. The polarization 214 of light beam 208 is orthogonal to the polarization 216 of light beam 210. The light beams 208, 210 interfere with each other and produce a polarization pattern on the sample 212. The sample 212 can be placed very close to the quarter wave plate 206, which makes the system very compact and involves few elements. The only required elements are the sample 212, the quarter wave plate 206, the Wollaston prism 204, and the transmitted light beam 202. The issue with this system is that the Wollaston prism 204 is made out of calcite, and there is a limit on the aperture size that you can acquire. For example, a Wollaston prism 204 that is 2 inches or larger is not possible due to not being able to find the materials large enough in nature to create a Wollaston prism 204 that large.

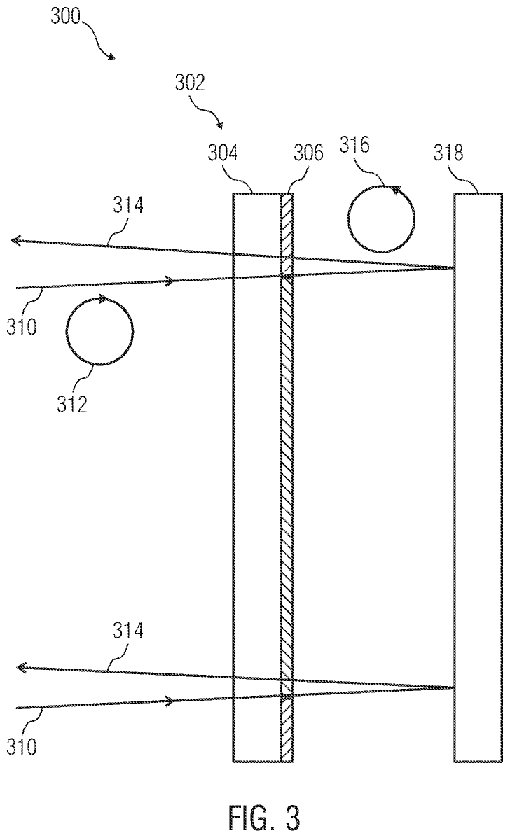

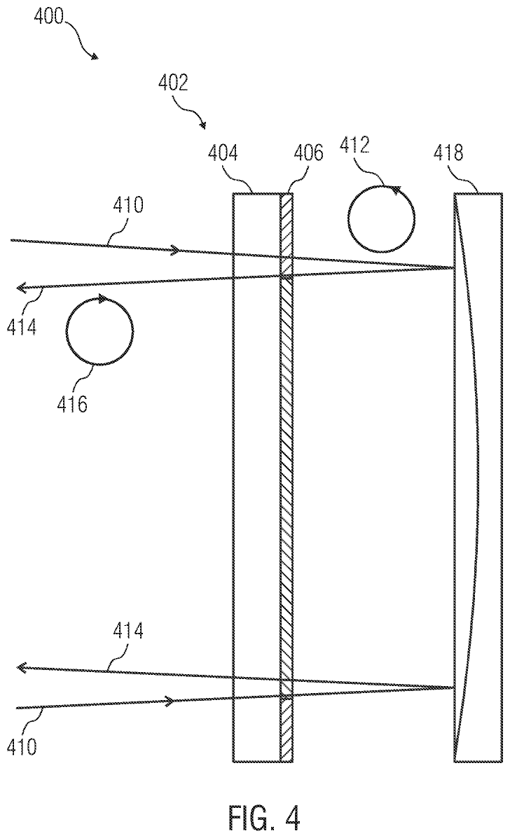

In various aspects, the present disclosure provides fabrication setups for creating optical elements through holographic fabrication. The fabrication setups for holographic fabrication of this disclosure employ fewer elements than previous systems. In one general aspect, the fabrication setups according to the present disclosure comprise a reflector, a sample, and a transmitted light beam. FIGS. 3 and 4 show two aspects of fabrication setups to create two different types of birefringent optical elements, where FIG. 3 shows a fabrication setup 300 to create a beam steering birefringent grating and FIG. 4 shows a fabrication setup 400 to create a birefringent lens that can either focus a beam or de-focus (diverge) a beam.

Referring to FIG. 3, a transmitted light beam 310, which is circularly polarized and has a polarization 312, travels along an optical path through the optical element 302. The transmitted light beam 310 passes through first a substrate 304 and then a photosensitive film 306 of the optical element 302 and continues along the optical path. In one aspect, the photosensitive film 306 may be spin coated on the substrate prior to transmitting the light beam 310. The thickness of the film may be selected to be less than 200 nm. The transmitted light beam 310 then reflects off of a reflector 318 which is at an angle with respect to transmitted light beam 310. The angle is selected based on the pitch of the desired birefringent grating being fabricated. The reflection produces a reflected light beam 314 that has a different polarization 316. The polarization 316 of the reflected light beam 314 is orthogonal to the polarization 312 of the transmitted light beam 310. The reflected light beam 314 continues along the optical path through the optical element 302, first passing through the film 306 and then the substrate 304. The transmitted light beam 310 and the reflected light beam 314 with orthogonal circular polarizations interfere with each other to produce a polarization pattern that is transferred to the photosensitive film 306. The next step in creating a birefringent optical element (grating) is to take the optical element 302 and apply liquid crystal against the photosensitive film 306, where the film works as an alignment layer for the liquid crystal.

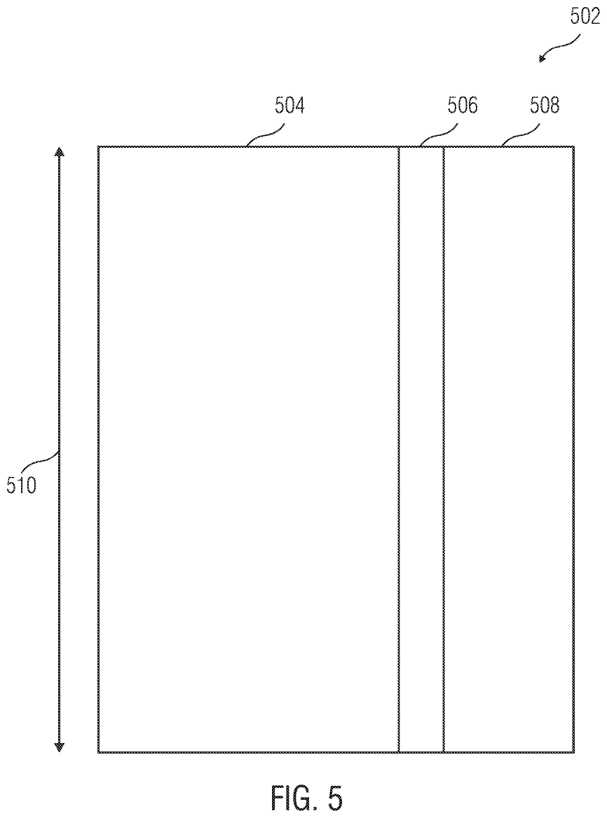

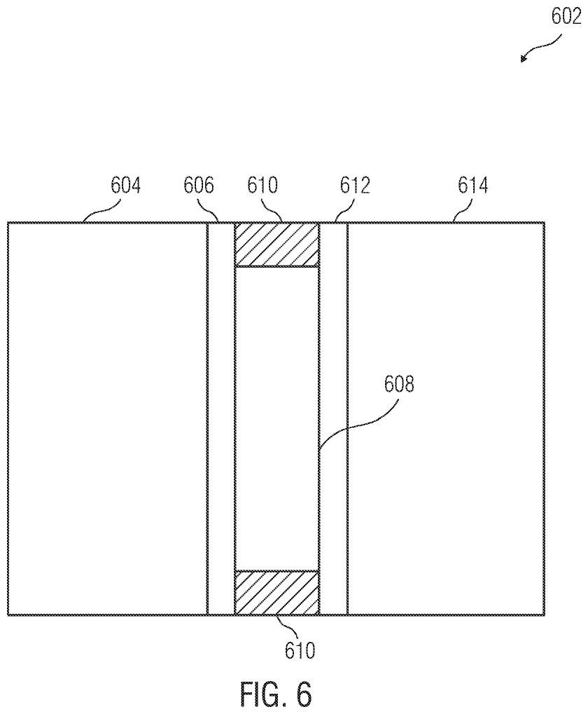

The liquid crystal layer can be applied using various methods. One method may be employed for applying liquid crystal that can be polymerized and another method may be employed for applying liquid crystal that cannot be polymerized. For the method with polymerized liquid crystal, referring to FIG. 5, an optical element 502 is created from a substrate 504 and a photosensitive film 506 that was coated onto the substrate 504. The photosensitive film 506 has been exposed to a desired polarization pattern through the method described in FIG. 3. The liquid crystal 508 is applied to optical element 502 by coating the liquid crystal onto the film 506, where the polarization pattern on the film 506 is reproduced on the liquid crystal 508. The liquid crystal 508 is then polymerized to lock its structure. The process of coating the liquid crystal 508 and polymerizing it is repeated multiple times to maintain the alignment and get a desired thickness. The liquid crystal layer thickness may be selected in the range from a few microns up to 10s of microns, for example. For the method with liquid crystal that cannot be polymerized, referring to FIG. 6, an optical element 602 is created from a substrate 604 and a film 606 that was spin coated onto the substrate 604. The film 606 has been exposed to a desired polarization pattern through the method described in FIG. 3. A second substrate 614 has a film 612 spin coated onto one side of the substrate 614. The film 612 does not need to be exposed to a polarization pattern. Substrates 604 with film 606 and substrate 614 with film 612 are glued together with a spacer material 610 provided to control the distance between substrate 604 and the substrate 614. A non-limiting example of spacer material is parallel stripes of mylar film, or glass beads of uniform size applied to one surface. The volume between the spacer material 610 is filled with liquid crystal 608, so that the thickness of the spacer material 610 is the thickness of the liquid crystal 608 layer. The liquid crystal 608 reproduces the polarization pattern on the film 606. The film 612 being against the liquid crystal promotes the liquid crystal to reproduce the polarization pattern on film 606. Both of the methods discussed above are non-limiting examples of how to create a birefringent optical element once the film 606 has been exposed to a polarization pattern through the method described in FIG. 3.

Referring to FIG. 3, there is an additional aspect where the fabrication setup includes a film disposed on the opposite side of the substrate, so that the film faces away from the reflector.

Referring still to FIG. 3, the material for the substrate 304 may be glass or fused silica but could be made of other materials and may have a thickness between 0.5 mm to 1 cm. Smaller or thicker substrates may be employed in other aspects. A photosensitive film 306 with a low absorption, e.g. less than 10% absorption, may be selected to maintain a better intensity match between the two interfering beams and allows for a higher contrast in the polarization pattern. Substrate interfaces may be optically coupled, e.g. coated with anti-reflective coatings, to suppress Fresnel reflections that will similarly reduce contrast in the polarization pattern. The reflector 318 is typically a metal mirror, but the reflector 318 could also be a mirror with dielectric coatings. The reflector 318 could be any material capable of controlling the polarization 316 of the reflected light beam 314 relative to the polarization 312 of the transmitted light beam 310. The optical element 302 can be placed close to the reflector 318 allowing the fabrication setup 300 to be compact and resistant to vibrations. This fabrication setup 300 is not limited to a small aperture size and is not as expensive as the prior art to fabricate birefringent optical elements of large sizes. This fabrication setup 300 overcomes the limitations of the typical holographic setup 100 and the birefringent element based holographic setup 200. Additionally, the fabrication setup 300 can be used to fabricate a birefringent optical element of any desired size small or large, where small relates to optical elements that are smaller than 1 inch and large relates to optical elements 1 inch or greater. The fabrication setup is particularly beneficial for producing large substrates from 4 inches to 12 inches due to it being the only method to produce birefringent optical elements this large and be compact with a small air path.

Referring to FIG. 4, a transmitted light beam 410, which has a polarization 412, travels along an optical path through the optical element 402. The transmitted light beam 410 passes through first a substrate 404 and then a photosensitive film 406 of the optical element 402 and continues along the optical path. The photosensitive film 406 is spin coated on the substrate prior to transmitting the light beam 410. The thickness of the photosensitive film is typically less than 200 nm. The transmitted light beam 410 then reflects off of a curved reflector 418 producing a reflected light beam 414 that has a different polarization 416. The curvature of the reflector is determined based on the properties desired from the birefringent lens. The polarization 416 of the reflected light beam 414 is orthogonal to the polarization 412 of the transmitted light beam 410. The reflected light beam 414 continues along the optical path through the lens 402, first passing through the film 406 and then the substrate 404. The transmitted light beam 410 and the reflected light beam 414 interfere with each other to produce a polarization pattern that is applied to the film 406. The next step in creating a birefringent optical element is to take the element 402 and apply liquid crystal against the film 406, where the film works as an alignment layer for the liquid crystal.

The liquid crystal layer can be applied using various methods. One method is for applying liquid crystal that can be polymerized and another method is for applying liquid crystal that cannot be polymerized. For the method with polymerized liquid crystal, referring to FIG. 5, an optical element 502 is created from a substrate 504 and a film 506 that was spin coated onto the substrate 504. The photosensitive film 506 has been exposed to a desired polarization pattern through the method described in FIG. 4. The liquid crystal 508 is applied to the optical element 502 by coating the liquid crystal onto the film 506, where the polarization pattern on the film 506 is reproduced on the liquid crystal 508. The liquid crystal 508 is then polymerized to lock its structure. The process of coating the liquid crystal 508 and polymerizing it may be repeated multiple times to maintain the alignment and get a desired thickness. The liquid crystal layer thickness may be selected in a range from a few microns up to 10s of microns, for example. For the method with liquid crystal that cannot be polymerized, referring to FIG. 6, an optical element 602 is created from a substrate 604 and a film 606 that was spin coated onto the substrate 604. The film 606 has been exposed to a desired polarization pattern through the method described in FIG. 4. A second substrate 614 has a film 612 spin coated onto one side of the substrate 614. The film 612 does not need to be exposed to a polarization pattern. The substrates 604 and 614 are attached together with a spacer material 610 provided between the two. A non-limiting example of spacer material is parallel stripes of mylar film, or glass beads of uniform size applied to one surface. The volume inside of the spacer material 610 is filled with liquid crystal 608, so that the thickness of the spacer material 610 is the thickness of the liquid crystal 608 layer. The liquid crystal 608 reproduces the polarization pattern on the film 606. The film 612 being against the liquid crystal promotes the liquid crystal to reproduce the polarization pattern on film 606. Both of the methods discussed above are non-limiting examples of how to create birefringent optical element once the film 606 has been exposed to a polarization pattern through the method described in FIG. 4.

Referring to FIG. 4, there is an additional aspect where the method includes the film disposed on the opposite side of the substrate, so that the film faces away from the reflector.

Referring to FIG. 4, the substrate 404 may be made from glass or fused silica but could be made of other materials and includes a thickness of 0.5 mm to 1 cm. Smaller or thicker substrates may be employed in other aspects A photosensitive film 406 with a low absorption, e.g. less than 10% absorption, may be selected to maintain a better intensity match between the two interfering beams and allows for a higher contrast in the polarization pattern created. Substrate interfaces may be optically coupled, e.g. coated with anti-reflective coatings, to suppress Fresnel reflections that will similarly reduce contrast in the polarization pattern. The reflector 418 may be a metal mirror, but the reflector 418 could also be a dielectric mirror with phase coatings. The reflector 418 could be any material capable of controlling the polarization 416 of the reflected light beam 414 relative to the polarization 412 of the transmitted light beam 410. The lens 402 can be placed close to the reflector 418 allowing the fabrication setup 400 to be compact and resistant to vibrations. This fabrication setup 400 is not limited to a small aperture size and is not as expensive as the prior art to fabricate birefringent lenses of large sizes. This fabrication setup 400 overcomes the limitations of the typical holographic setup 100 and the birefringent element based holographic setup 200. Additionally, the fabrication setup 400 can be employed to fabricate a birefringent lens of any desired size small or large, where small relates to lenses that are smaller than 1 inch and large relates to lenses 1 inch or greater. The fabrication setup is particularly beneficial for producing large substrates from 4 inches to 12 inches due to it being the only method to produce lenses this large and be compact with a small air path.

The method of creating the two types of birefringent optical elements in FIGS. 3 and 4 follow the same general steps that are described in the flow diagram of FIG. 7. To start, the general method 700 to create a birefringent optical element, a reflector is placed in an optical path, step 702. A low absorption photosensitive film is applied on the side of a substrate, step 704. The film is employed as an alignment layer for liquid crystal that is added later (see step 720). The substrate is added to the optical path proximal to the reflector such that the side with the photosensitive film faces the reflector, step 706. A light beam is transmitted with a desired polarization along the optical path, step 710. At step 712, the transmitted light beam travels through the substrate and film, where the transmitted light beam first passes through the substrate and then the film that is against the substrate. Continuing step 712, the transmitted light beam exits the film and travels along the optical path and is reflected off the reflector. The reflected light beam has a different desired polarization than the transmitted light beam. At step 714, the reflected light beam travels back through the film and then the substrate. At step 716, the transmitted light beam and the reflected light beam interfere with each other to produce a polarization pattern. At step 718, the polarization pattern is transferred to the structure of the first film such that the structure of the film is changed to match the polarization pattern. The method 700 ends at step 720 by applying the liquid crystal against the film in such a way that the liquid crystal matches the alignment of the film. The structure of the liquid crystal is then locked and a birefringent optical element is created. The general method 700 describes the general steps used in the process to create birefringent optical elements described in FIGS. 3 and 4.

Various examples have been described with reference to certain disclosed aspects. The various aspects are presented for purposes of illustration and not limitation. One skilled in the art will appreciate that various changes, adaptations, and modifications can be made without departing from the scope of the disclosure or the scope of the appended claims.

### EXAMPLES

Various aspects of the subject matter described herein are set out in the following numbered examples.

Example 1—A method for creating optical elements through holographic fabrication. The method comprises positioning a reflector in an optical path, and disposing a first photosensitive film on a side of a first substrate. The method further comprises transmitting a light beam at a first polarization from a light source along the optical path, wherein the light beam enters the first substrate on the side facing away from the reflector and exits the first substrate on the side facing the reflector with the first photosensitive film and continues toward the reflector. The method further comprises reflecting the light beam off the reflector, wherein the reflected light beam has a second polarization, and receiving the reflected light beam through the first photosensitive film and the first substrate. The transmitted light beam and reflected light beam interfere with each other to produce a polarization pattern that is transferred to an alignment pattern of the first photosensitive film. The method further comprises applying a liquid crystal layer to the first photosensitive film to reproduce the alignment pattern of the first photosensitive film on the liquid crystal layer.

Example 2—The method of Example 1, further comprising disposing the first substrate proximal to the reflector along the optical path, wherein the side of the first substrate with the first photosensitive film faces the reflector and another side faces away from the reflector.

Example 3—The method of Examples 1 or 2, comprising receiving therethrough the transmitted light beam from the light source at an angle with respect to the reflector.

Example 4—The method of Examples 1, 2, or 3, comprising receiving the reflected light beam with a second polarization that is orthogonal to the first polarization.

Example 5—The method of Examples 1, 2, 3, or 4, comprising disposing the first film layer with a low light absorption below 10%.

Example 6—The method of Examples 1, 2, 3, 4, or 5, comprising positioning the reflector that comprises a metal material.

Example 7—The method of Examples 1, 2, 3, 4, 5, or 6, comprising positioning the reflector that comprises of a dielectric material.

Example 8—The method of Examples 1, 2, 3, 4, 5, 6, or 7, comprising applying the liquid crystal layer by coating the liquid crystal layer onto the first film to a predetermined thickness.

Example 9—The method of Example 8, comprising polymerizing the liquid crystal layer to lock the structure of the liquid crystal layer to produce a birefringent optical element.

Example 10—The method of Examples 1, 2, 3, 4, 5, 6, or 7, comprising adding the liquid crystal layer by providing a second substrate comprising a second film layer disposed on a surface of the second substrate, positioning and attaching a thickness spacer against the first film, applying the liquid crystal layer by filling the volume inside of the spacer with liquid crystal, and positioning and attaching the second substrate against the spacer and liquid crystal. The liquid crystal is directly between the first and second film and held in place by the surrounding spacer. The thickness of the spacer is the thickness of the liquid crystal layer.

Example 11—A birefringent optical element produced by a method comprising positioning a reflector in an optical path, disposing a first photosensitive film on a side of a first substrate, and disposing the first substrate proximal to the reflector along the optical path, wherein the side of the first substrate with the first photosensitive film faces the reflector and another side faces away from the reflector. The method further comprises transmitting a light beam at a first polarization from a light source along the optical path, wherein the light beam enters the first substrate on the side facing away from the reflector and exits the first substrate on the side facing the reflector with the first photosensitive film and continues toward the reflector. The method further comprises reflecting the light beam off the reflector, wherein the reflected light beam has a second polarization, and receiving the reflected light beam through the first film and the first substrate, wherein the transmitted light beam and reflected light beam interfere with each other to produce a polarization pattern that is transferred to an alignment pattern of the first photosensitive film. The method further comprises applying a liquid crystal layer to the first film to reproduce the alignment pattern of the first film on the liquid crystal layer, applying the liquid crystal layer by coating the liquid crystal layer onto the first film to a predetermined thickness, and polymerizing the liquid crystal layer to lock the structure of the liquid crystal layer.

Example 12—A birefringent optical element produced by a method comprising positioning a reflector in an optical path, disposing a first photosensitive film on a side of a first substrate, and disposing the first substrate proximal to the reflector along the optical path, wherein the side of the first substrate with the first photosensitive film faces the reflector and another side faces away from the reflector. The method further comprises transmitting a light beam at a first polarization from a light source along the optical path, wherein the light beam enters the first substrate on the side facing away from the reflector and exits the first substrate on the side facing the reflector with the first film and continues toward the reflector. The method further comprises reflecting the light beam off the reflector, wherein the reflected light beam has a second polarization, and receiving the reflected light beam through the first photosensitive film and the first substrate, wherein the transmitted light beam and reflected light beam interfere with each other to produce a polarization pattern that is transferred to an alignment pattern of the first film. The method further comprises providing a second substrate comprising a second film layer disposed on a surface of the second substrate, and positioning and attaching a thickness spacer on the first substrate against the first film, wherein the thickness of the spacer is the thickness of a liquid crystal layer. The method further comprises applying the liquid crystal layer by filling the volume inside of the spacer with liquid crystal, and positioning and attaching the second substrate against the spacer, wherein the liquid crystal is directly between the first and second film and held in place by the surrounding spacer.

Example 13—A method for creating optical elements through holographic fabrication. The method comprising positioning a curved reflector in an optical path, and disposing a first photosensitive film on a side of a first substrate. The method further comprises transmitting a light beam at a first polarization from a light source along the optical path, wherein the light beam enters the first substrate on the side facing away from the reflector and exits the first substrate on the side facing the reflector with the first photosensitive film and continues toward the reflector. The method further comprises reflecting the light beam off the reflector, wherein the reflected light beam has a second polarization, and receiving the reflected light beam through the first photosensitive film and the first substrate, wherein the transmitted light beam and reflected light beam interfere with each other to produce a polarization pattern that is transferred to an alignment pattern of the first film. The method further comprises applying a liquid crystal layer to the first film to reproduce the alignment pattern of the first film on the liquid crystal layer.

Example 14—The method of Example 13, further comprising disposing the first substrate proximal to the reflector along the optical path, wherein the side of the first substrate with the first photosensitive film faces the reflector and another side faces away from the reflector.

Example 15—The method of Examples 13 or 14, comprising positioning a curved reflector in an optical path; wherein the curved reflector is aspheric to minimize aberrations in the optical element

Example 16—The method of Examples 13, 14, or 15, comprising receiving the reflected light beam with a second polarization that is orthogonal to the first polarization.

Example 17—The method of Examples 13, 14, 15, or 16, comprising disposing the first film layer with a low light absorption below 10%.

Example 18—The method of Examples 13, 14, 15, 16, or 17, comprising positioning the curved reflector that comprises a metal material.

Example 19—The method of Examples 13, 14, 15, 16, 17, or 18, comprising positioning the curved reflector that comprises of a dielectric material.

Example 20—The method of Examples 13, 14, 15, 16, 17, 18, or 19, comprising applying the liquid crystal layer by coating the liquid crystal layer onto the first film to a predetermined thickness.

Example 21—The method of Example 20, comprising polymerizing the liquid crystal layer to lock the structure of the liquid crystal layer to produce a birefringent lens.

Example 22—The method of Examples 13, 14, 15, 16, 17, 18, or 19, comprising applying the liquid crystal layer by providing a second substrate comprising a second film layer disposed on a surface of the second substrate, positioning and attaching a thickness spacer on the first substrate against the first film, applying the liquid crystal by filling the volume inside of the spacer with liquid crystal, and positioning and attaching the second substrate against the spacer. The thickness of the spacer is the thickness of the liquid crystal layer. The liquid crystal is directly between the first and second film and held in place by the surrounding spacer to produce a birefringent lens.

Example 23—A birefringent lens produced by a method comprising positioning a curved reflector in an optical path, disposing a first photosensitive film on a side of a first substrate, and disposing the first substrate proximal to the reflector along the optical path, wherein the side of the first substrate with the first photosensitive film faces the reflector and another side faces away from the reflector. The method further comprises transmitting a light beam at a first polarization from a light source along the optical path, wherein the light beam enters the first substrate on the side facing away from the reflector and exits the first substrate on the side facing the reflector with the first photosensitive film and continues toward the reflector. The method further comprises reflecting the light beam off the reflector, wherein the reflected light beam has a second polarization, and receiving the reflected light beam through the first film and the first substrate, wherein the transmitted light beam and reflected light beam interfere with each other to produce a polarization pattern that is transferred to an alignment pattern of the first photosensitive film. The method further comprises applying a liquid crystal layer to the first film to reproduce the alignment pattern of the first photosensitive film on the liquid crystal layer, applying the liquid crystal layer by coating the liquid crystal layer onto the first film to a predetermined thickness, and polymerizing the liquid crystal layer to lock the structure of the liquid crystal layer.

Example 24—A birefringent lens produced by a method comprising positioning a curved reflector in an optical path, disposing a first photosensitive film on a side of a first substrate, and disposing the first substrate proximal to the reflector along the optical path, wherein the side of the first substrate with the first photosensitive film faces the reflector and another side faces away from the reflector. The method further comprises transmitting a light beam at a first polarization from a light source along the optical path, wherein the light beam enters the first substrate on the side facing away from the reflector and exits the first substrate on the side facing the reflector with the first photosensitive film and continues toward the reflector. The method further comprises reflecting the light beam off the reflector, wherein the reflected light beam has a second polarization, and receiving the reflected light beam through the first film and the first substrate, wherein the transmitted light beam and reflected light beam interfere with each other to produce a polarization pattern that is transferred to an alignment pattern of the first photosensitive film. The method further comprises providing a second substrate comprising a second film layer disposed on a surface of the second substrate, and positioning and attaching a thickness spacer around the outside of the first substrate against the first film, wherein the thickness of the spacer is the thickness of the liquid crystal layer. The method further comprises applying the liquid crystal layer by filling the volume inside of the spacer with liquid crystal, and positioning and attaching the second substrate against the spacer, wherein the liquid crystal is directly between the first and second film and held in place by the surrounding spacer.

1. A method for creating optical elements through holographic fabrication, the method comprising:
positioning a reflector in an optical path;
disposing a first photosensitive film on a side of a first substrate;
transmitting a light beam at a first polarization from a light source along the optical path, wherein the light beam enters the first substrate on a side facing away from the reflector and exits the first substrate on a side facing the reflector with the first photosensitive film and continues toward the reflector;
reflecting the light beam off the reflector, wherein the reflected light beam has a second polarization;
receiving the reflected light beam through the first photosensitive film and the first substrate, wherein the transmitted light beam and reflected light beam interfere with each other to produce a polarization pattern that is transferred to an alignment pattern of the first photosensitive film; and
applying a liquid crystal layer to the first photosensitive film to reproduce the alignment pattern of the first photosensitive film on the liquid crystal layer.

2. The method of claim 1, further comprising disposing the first substrate proximal to the reflector along the optical path, wherein the side of the first substrate with the first photosensitive film faces the reflector and another side faces away from the reflector;

3. The method of claim 1, comprising receiving therethrough the transmitted light beam from the light source at an angle with respect to the reflector.

4. The method of claim 1, comprising receiving the reflected light beam with a second polarization that is orthogonal to the first polarization.

5. The method of claim 1, comprising disposing the first film layer with a low light absorption below 10%.

6. The method of claim 1, comprising positioning the reflector that comprises a metal material.

7. The method of claim 1, comprising positioning the reflector that comprises of a dielectric material.

8. The method of claim 1, comprising applying the liquid crystal layer by coating the liquid crystal layer onto the first film to a predetermined thickness.

9. The method of claim 8, comprising polymerizing the liquid crystal layer to lock the structure of the liquid crystal layer to produce a birefringent optical element.

10. The method of claim 1, comprising adding the liquid crystal layer by:
providing a second substrate comprising a second film layer disposed on a surface of the second substrate;
positioning and attaching a thickness spacer against the first film, wherein the thickness of the spacer is the thickness of the liquid crystal layer;
applying the liquid crystal layer by filling the volume inside of the spacer with liquid crystal; and
positioning and attaching the second substrate against the spacer and liquid crystal, wherein the liquid crystal is directly between the first and second film and held in place by the surrounding spacer.

11. A birefringent optical element produced by a method comprising:
positioning a reflector in an optical path;
disposing a first photosensitive film on a side of a first substrate;
disposing the first substrate proximal to the reflector along the optical path, wherein the side of the first substrate with the first photosensitive film faces the reflector and another side faces away from the reflector;
transmitting a light beam at a first polarization from a light source along the optical path, wherein the light beam enters the first substrate on the side facing away from the reflector and exits the first substrate on the side facing the reflector with the first photosensitive film and continues toward the reflector;
reflecting the light beam off the reflector, wherein the reflected light beam has a second polarization;
receiving the reflected light beam through the first film and the first substrate, wherein the transmitted light beam and reflected light beam interfere with each other to produce a polarization pattern that is transferred to an alignment pattern of the first photosensitive film;
applying a liquid crystal layer to the first film to reproduce the alignment pattern of the first film on the liquid crystal layer;
applying the liquid crystal layer by coating the liquid crystal layer onto the first film to a predetermined thickness; and
polymerizing the liquid crystal layer to lock the structure of the liquid crystal layer.

12. A birefringent optical element produced by a method comprising,
positioning a reflector in an optical path;
disposing a first photosensitive film on a side of a first substrate;
disposing the first substrate proximal to the reflector along the optical path, wherein the side of the first substrate with the first photosensitive film faces the reflector and another side faces away from the reflector;
transmitting a light beam at a first polarization from a light source along the optical path, wherein the light beam enters the first substrate on the side facing away from the reflector and exits the first substrate on the side facing the reflector with the first film and continues toward the reflector;
reflecting the light beam off the reflector, wherein the reflected light beam has a second polarization;
receiving the reflected light beam through the first photosensitive film and the first substrate, wherein the transmitted light beam and reflected light beam interfere with each other to produce a polarization pattern that is transferred to an alignment pattern of the first film;
providing a second substrate comprising a second film layer disposed on a surface of the second substrate;
positioning and attaching a thickness spacer on the first substrate against the first film, wherein the thickness of the spacer is the thickness of a liquid crystal layer;
applying the liquid crystal layer by filling the volume inside of the spacer with liquid crystal; and
positioning and attaching the second substrate against the spacer, wherein the liquid crystal is directly between the first and second film and held in place by the surrounding spacer.

13. A method for creating optical elements through holographic fabrication, the method comprising:
positioning a curved reflector in an optical path;
disposing a first photosensitive film on a side of a first substrate;
disposing the first substrate proximal to the reflector along the optical path, wherein a side of the first substrate with the first photosensitive film faces the reflector and another side faces away from the reflector;
transmitting a light beam at a first polarization from a light source along the optical path, wherein the light beam enters the first substrate on the side facing away from the reflector and exits the first substrate on the side facing the reflector with the first photosensitive film and continues toward the reflector;
reflecting the light beam off the reflector, wherein the reflected light beam has a second polarization;
receiving the reflected light beam through the first photosensitive film and the first substrate, wherein the transmitted light beam and reflected light beam interfere with each other to produce a polarization pattern that is transferred to an alignment pattern of the first film; and
applying a liquid crystal layer to the first film to reproduce the alignment pattern of the first film on the liquid crystal layer.

14. The method of claim 13, further comprising disposing the first substrate proximal to the reflector along the optical path, wherein the side of the first substrate with the first photosensitive film faces the reflector and another side faces away from the reflector;

15. The method of claim 13, comprising positioning a curved reflector in an optical path;
wherein the curved reflector is aspheric to minimize aberrations in the optical element

16. The method of claim 13, comprising receiving the reflected light beam with a second polarization that is orthogonal to the first polarization.

17. The method of claim 13, comprising disposing the first film layer with a low light absorption below 10%.

18. The method of claim 13, comprising positioning the curved reflector that comprises a metal material.

19. The method of claim 13, comprising positioning the curved reflector that comprises of a dielectric material.

20. The method of claim 13, comprising applying the liquid crystal layer by coating the liquid crystal layer onto the first film to a predetermined thickness.

21. The method of claim 20, comprising polymerizing the liquid crystal layer to lock the structure of the liquid crystal layer to produce a birefringent lens.

22. The method of claim 13, comprising applying the liquid crystal layer by:
providing a second substrate comprising a second film layer disposed on a surface of the second substrate;
positioning and attaching a thickness spacer on the first substrate against the first film, wherein the thickness of the spacer is the thickness of the liquid crystal layer;
applying the liquid crystal layer by filling the volume inside of the spacer with liquid crystal; and
positioning and attaching the second substrate against the spacer, wherein the liquid crystal is directly between the first and second film and held in place by the surrounding spacer to produce a birefringent lens.

23. A birefringent lens produced by a method comprising:
positioning a curved reflector in an optical path;
disposing a first photosensitive film on a side of a first substrate;
disposing the first substrate proximal to the reflector along the optical path, wherein the side of the first substrate with the first photosensitive film faces the reflector and another side faces away from the reflector;
transmitting a light beam at a first polarization from a light source along the optical path, wherein the light beam enters the first substrate on the side facing away from the reflector and exits the first substrate on the side facing the reflector with the first photosensitive film and continues toward the reflector;
reflecting the light beam off the reflector, wherein the reflected light beam has a second polarization;
receiving the reflected light beam through the first film and the first substrate, wherein the transmitted light beam and reflected light beam interfere with each other to produce a polarization pattern that is transferred to an alignment pattern of the first photosensitive film;
applying a liquid crystal layer to the first film to reproduce the alignment pattern of the first photosensitive film on the liquid crystal layer;
applying the liquid crystal layer by coating the liquid crystal layer onto the first film to a predetermined thickness; and
polymerizing the liquid crystal layer to lock the structure of the liquid crystal layer.

24. A birefringent lens produced by a method comprising:
positioning a curved reflector in an optical path;
disposing a first photosensitive film on a side of a first substrate;
disposing the first substrate proximal to the reflector along the optical path, wherein the side of the first substrate with the first photosensitive film faces the reflector and another side faces away from the reflector;
transmitting a light beam at a first polarization from a light source along the optical path, wherein the light beam enters the first substrate on the side facing away from the reflector and exits the first substrate on the side facing the reflector with the first photosensitive film and continues toward the reflector;
reflecting the light beam off the reflector, wherein the reflected light beam has a second polarization;
receiving the reflected light beam through the first film and the first substrate, wherein the transmitted light beam and reflected light beam interfere with each other to produce a polarization pattern that is transferred to an alignment pattern of the first photosensitive film;
providing a second substrate comprising a second film layer disposed on a surface of the second substrate;
positioning and attaching a thickness spacer around the outside of the first substrate against the first film, wherein the thickness of the spacer is the thickness of the liquid crystal layer;
applying the liquid crystal layer by filling the volume inside of the spacer with liquid crystal; and
positioning and attaching the second substrate against the spacer, wherein the liquid crystal is directly between the first and second film and held in place by the surrounding spacer.
